(19) United States
(12) Patent Application Publication
(10) Pub. No.: US 2001/0044209 A1
(43) Pub. Date: Nov. 22, 2001

(54) METHOD FOR MODIFICATION OF POLISHING PATTERN DEPENDENCE IN CHEMICAL MECHANICAL POLISHING

(76) Inventor: DAVID RUSSELL EVANS, BEAVERTON, OR (US)

Correspondence Address: Matthew D. Rabdau, Sharp Laboratories of America, Inc., 5750 N.W. Pacific Rim Blvd., CAMAS, WA, 98607, US

(21) Appl. No.: 09/270,606

(22) Filed: Mar. 17, 1999

(51) Int. Cl. H01L 21/302; H01L 21/461

(52) U.S. Cl. 438/692

(57) ABSTRACT

A method of CMP includes forming a CMP slurry containing cerium oxide; adding a slurry modifier to the slurry, wherein the slurry modifier polishes low structure areas at a substantially zero rate and polishes high structure areas at a rate approximating a blanket polishing rate; and polishing a structure using the modifier-contained slurry.

### FIELD OF THE INVENTION

This invention relates to integrated circuit fabrication, and specifically to a method of shallow trench isolation.

### BACKGROUND OF THE INVENTION

Pattern dependence, i.e., variation of chemical mechanical polishing (CMP) rate due to feature size and density, is a severe problem for fabrication of shallow trench isolation (STI) for advanced integrated circuits. This results in the removal of too little or too much of the intended structure, and may also lead to contamination of the wafer. One known way to overcome this problem is to include “dummy” structures in an IC for the sole purpose of controlling the CMP rate. This solution, however, places unacceptable restrictions on the design and functionality of IC devices.

### SUMMARY OF THE INVENTION

A method of CMP includes forming a CMP slurry containing cerium oxide; adding a slurry modifier to the slurry, wherein the slurry modifier polishes low structure areas at a substantially zero rate and polishes high structure areas at a rate approximating a blanket polishing rate; and polishing a structure using the modifier-contained slurry.

An object of the invention is to reduce or eliminate the effects of pattern dependence so that polishing rates will be substantially independent of feature size and density.

### BRIEF DESCRIPTION OF THE DRAWINGS

FIG. 1 depicts ideal polishing characteristics.

FIG. 2 depicts the characteristics of CMP of a silicon dioxide substrate using a conventional slurry.

FIG. 3 depicts CMP characteristic as a function of feature size and density.

FIG. 4 depicts the characteristics of CMP of a silicon dioxide substrate using a cerium oxide slurry.

FIG. 5 depicts the characteristics of CMP of a silicon dioxide substrate using a cerium oxide slurry with various pad sizes.

FIG. 6 depicts the characteristics of CMP of a silicon dioxide substrate using a cerium oxide slurry over a polish stop.

FIG. 7 depicts the effect of an ethylene glycol modifier on CMP using a cerium oxide slurry.

FIG. 8 depicts the effect of an ethylene glycol modifier on CMP using a cerium oxide slurry with increase down force.

### DETAILED DESCRIPTION OF THE PREFERRED EMBODIMENT

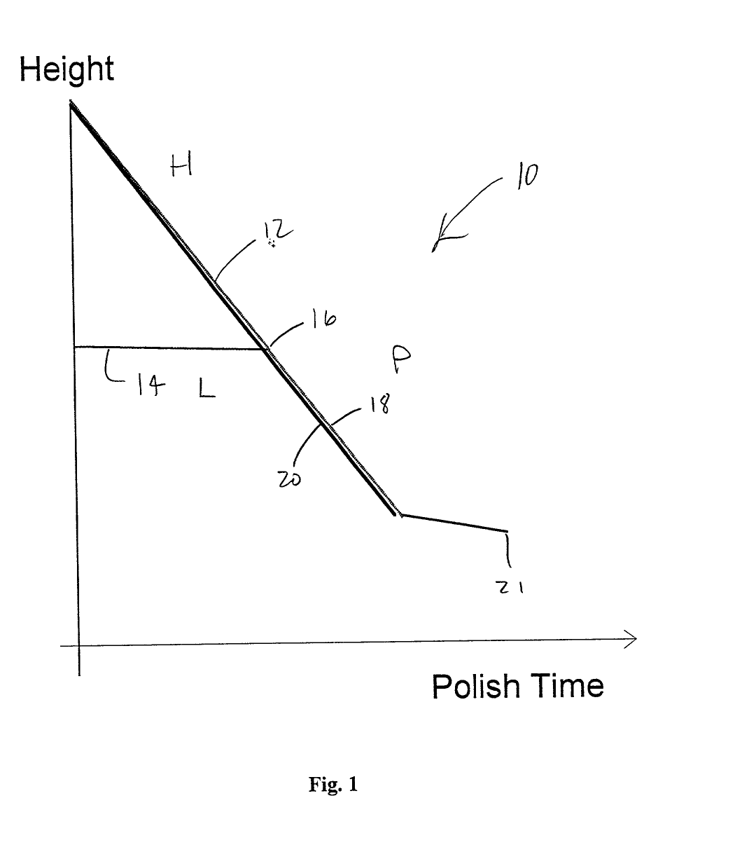

The essence of the present invention is the use of a modifier to control polishing characteristics so that they approximate the behavior shown in FIG. 1. The specific preferred implementation of this invention is for fabrication of shallow trench isolation (STI) for deep submicron integrated circuits.

Blanket removal rates are measured on unpatterned wafers. Ideal polishing characteristics are depicted in FIG. 1, generally at 10. Initially high structure areas, H, polish at a high polish rate 12 much faster than those low structure areas, L, which polish at a low area polish rate 14. In an ideal world, the low areas would not polish at all until the high areas had been leveled to the height of the low areas. As topography is removed, these rates converge at a convergence point 16, after which, the wafer is polished at a converged rate 18, in a planarized area P, which is substantially the same as a blanket rate 20, until the polishing process is terminated at 21. This convergence point, or planarization point, is dependent on feature size and density.

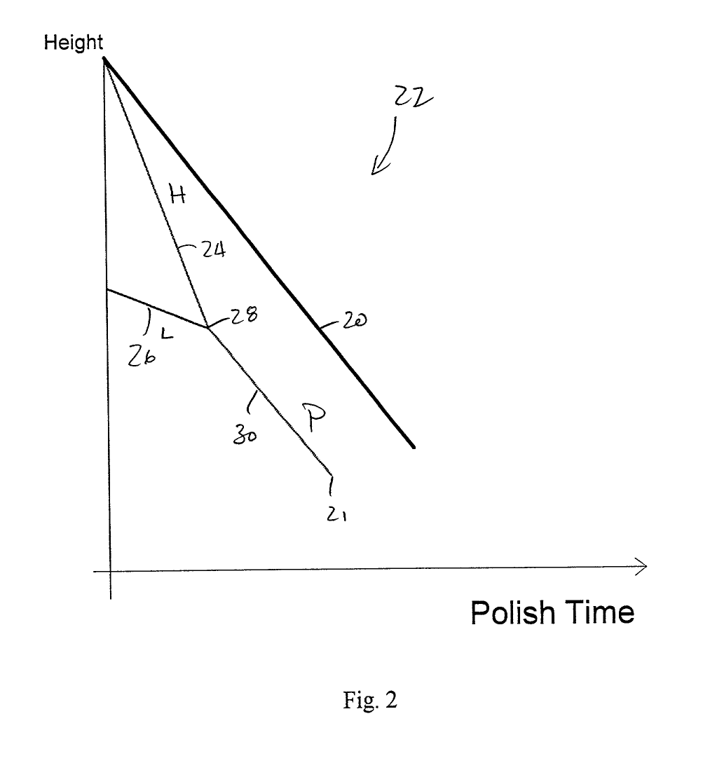

A typical real world polishing characteristic is shown in FIG. 2, generally at 22. A high structure area polish rate 24 is higher, meaning that high structure areas polish faster than any low structure areas, which polish at a low area rate 26, however, the low structure areas are still polished and worn away long before the convergence point 28 is reached. Once the convergence point is reached, the converged rate of polishing 30 is similar to that of the idealized blanket rate 20.

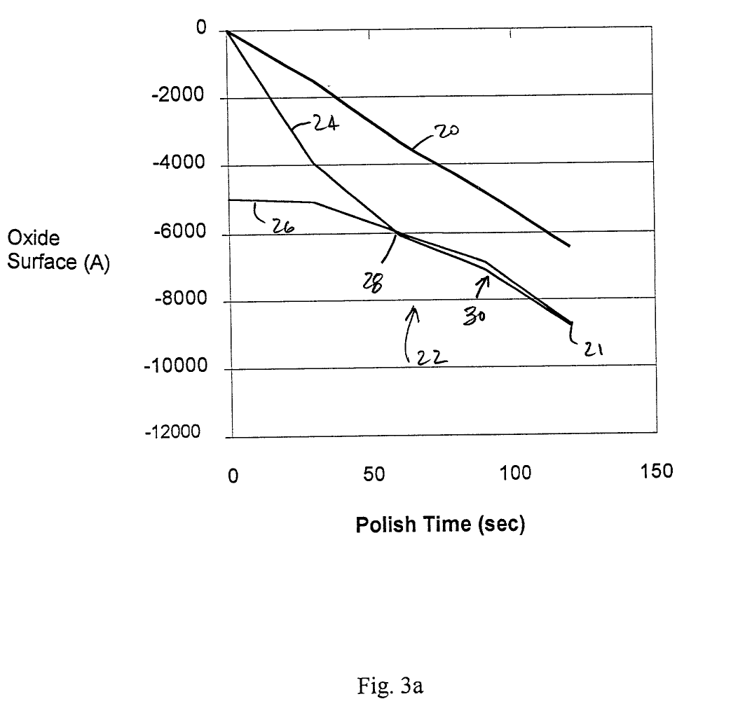

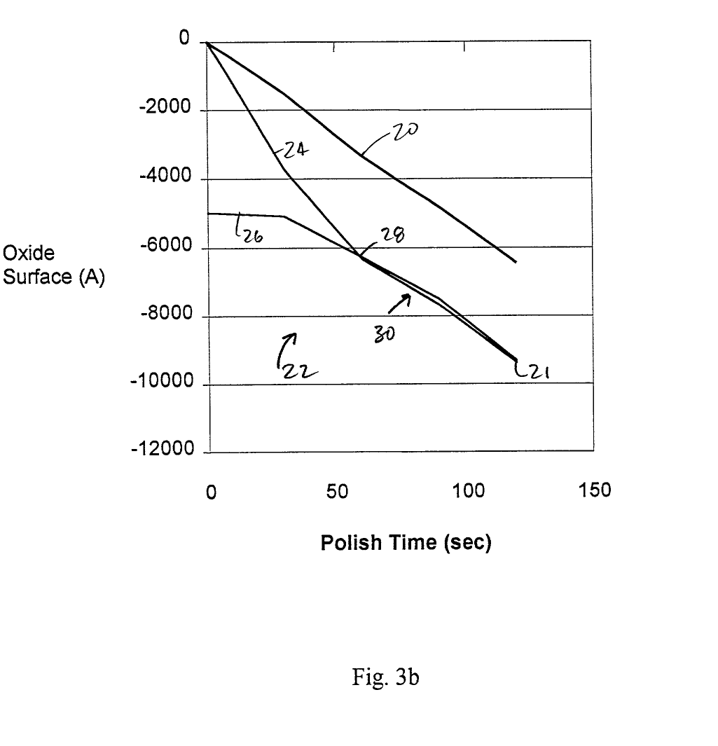

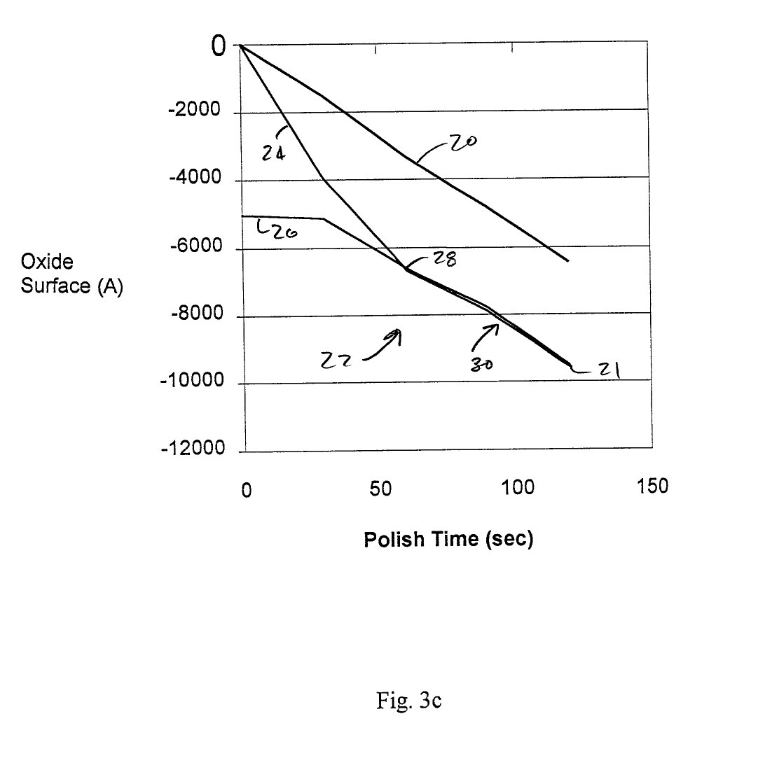

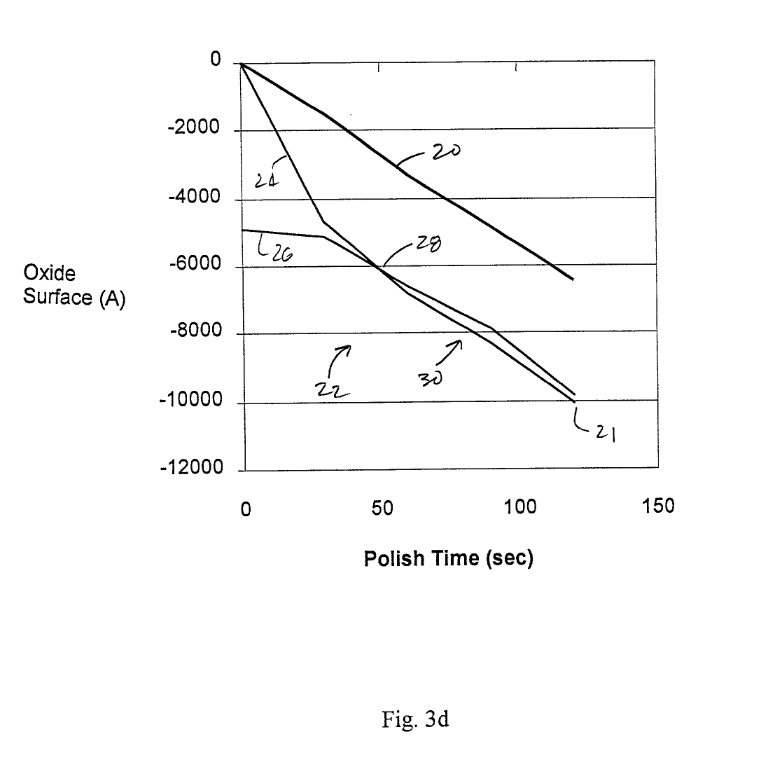

Specific examples of polishing characteristics are depicted in FIG. 3 for polishing data taken for four overall feature size scales. These are 2×2 μm, FIG. 3a; 4×4 μm, FIG. 3b; 8×8μm, FIG. 3c; and 16×l6 μm, FIG. 3d. For each size scale, drawn feature densities varying from 10% to 40% were measured, and a representative feature density of 25% is illustrated in the drawing figures. Clearly, the real data follows the typical behavior illustrated in FIG. 2. It is also clear that both feature size and density affect the time required to planarize the surface. This data illustrates an inherent limitation of the conventional case, wherein the slurry is a strong alkali solution, such as sodium hydroxide, potassium hydroxide or ammonium hydroxide, which are mixed with fused silica.

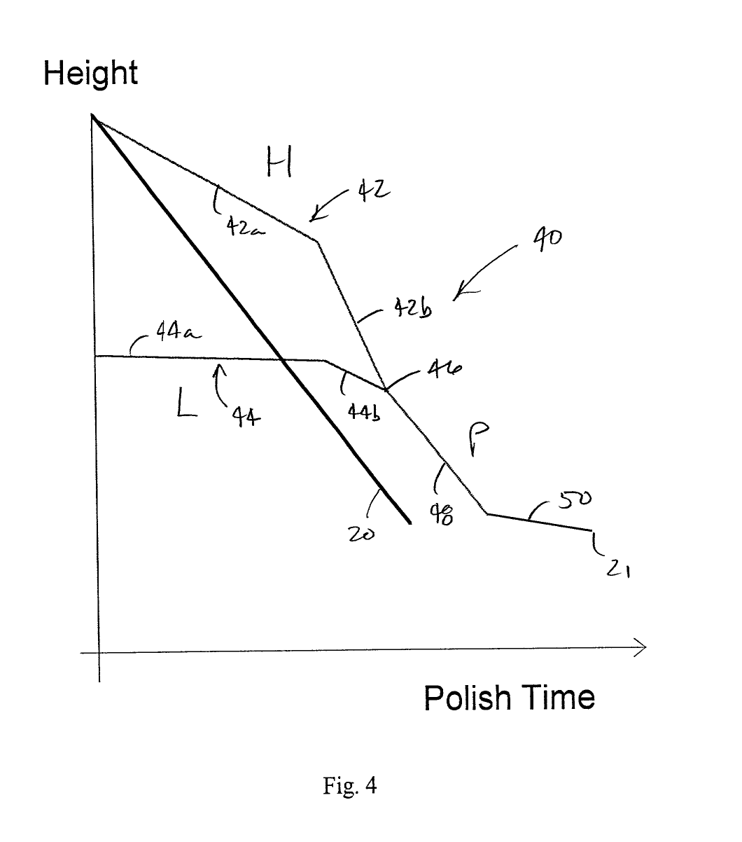

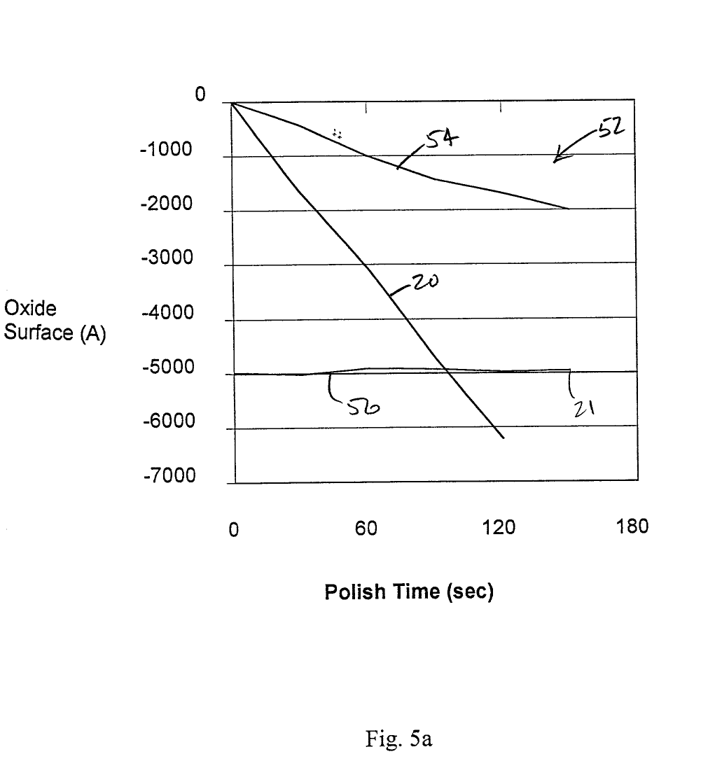

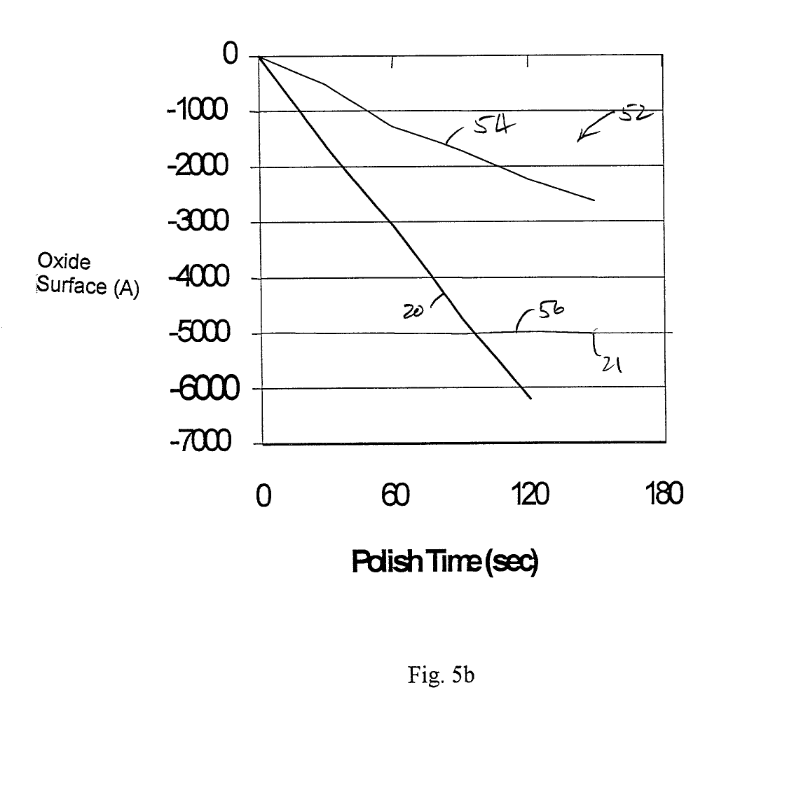

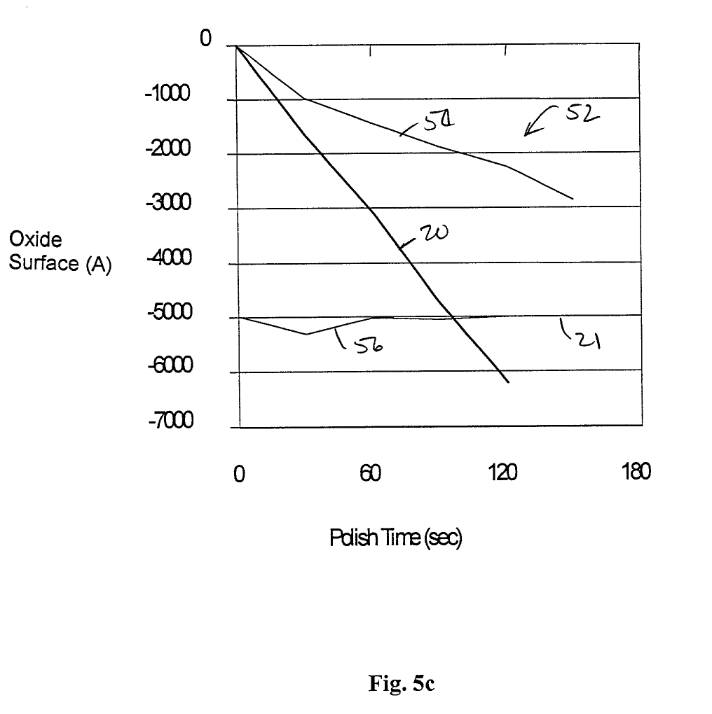

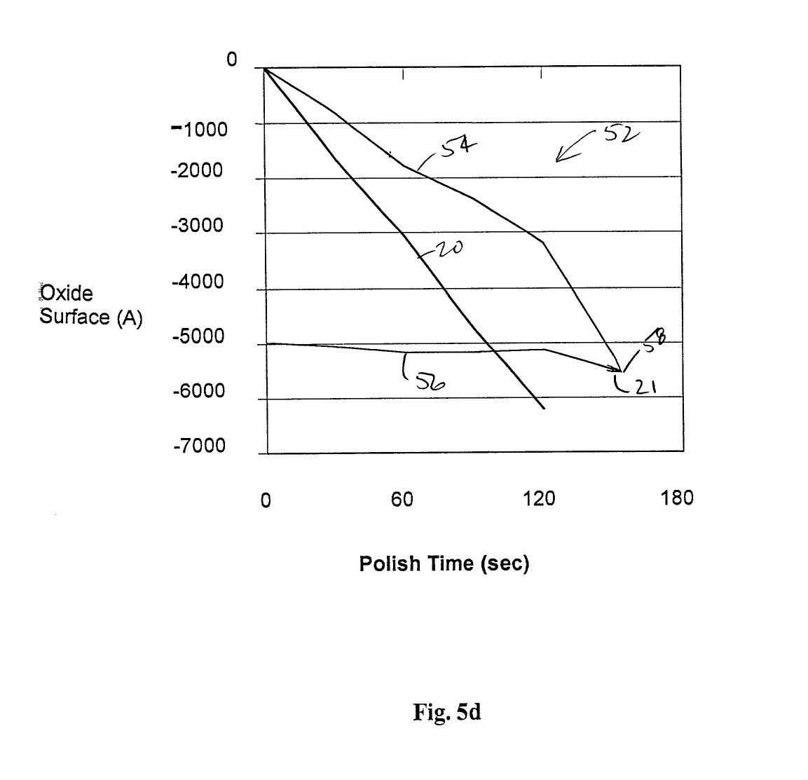

In the course of investigation of the polishing behavior of silicon dioxide using a slurry formulation containing ceria, i.e., cerium oxide, a different polishing characteristic is observed. This characteristic is illustrated generally at 40 in FIG. 4 and generally at 52 in FIG. 5.

Referring now to FIG. 4, a high polish rate 42 is greater than blanket rate 20, which, for the purpose of comparison, are measured on unpatterned wafers. A low area rate 44 converges with high area rate at a convergence point 46, after which structure is removed at a converged rate 48, until a polish stop rate 50 is encountered. An interesting feature using this type of slurry in CMP is the appearance of an initial removal rate 42a, for high areas of the features that is actually lower than blanket removal rate 20. A pre-convergence high area rate 42b may be the same as, or slightly greater than blanket removal rate 20. An initial low area rate 44a and a pre-convergence low area rate are essentially zero. Similarly, the removal rate for low features is essentially zero 46a. Conventional models of chemical mechanical polishing cannot explain such behavior.

An extreme case of this behavior is illustrated by characteristic 52 depicted in FIG. 5. Again, polishing data taken for four overall feature size scales. These are 2×2 μm, FIG. 5a; 4×4 μm, FIG. 5b; 8×8 μm, FIG. 5c; and 16×16 μm, FIG. 5d. For each size scale, drawn feature densities varying from 10% to 40% were measured, and a representative feature density of 25% is illustrated in the drawing figures. High area rates 54 may or may not shown initial and pre-convergence rates, while low area rates 56 are nearly zero. Only in FIG. 5d, is a convergence point 58 reached, and then only in limited instances, i.e., where the overall feature density is less than 15%. Very little of the low areas are removed, which is a desired characteristic, however, an insubstantial portion of the high areas are removed, which does not achieve the desired planarization. Clearly, It is only in the case of the largest scale features that substantial planarization is achieved

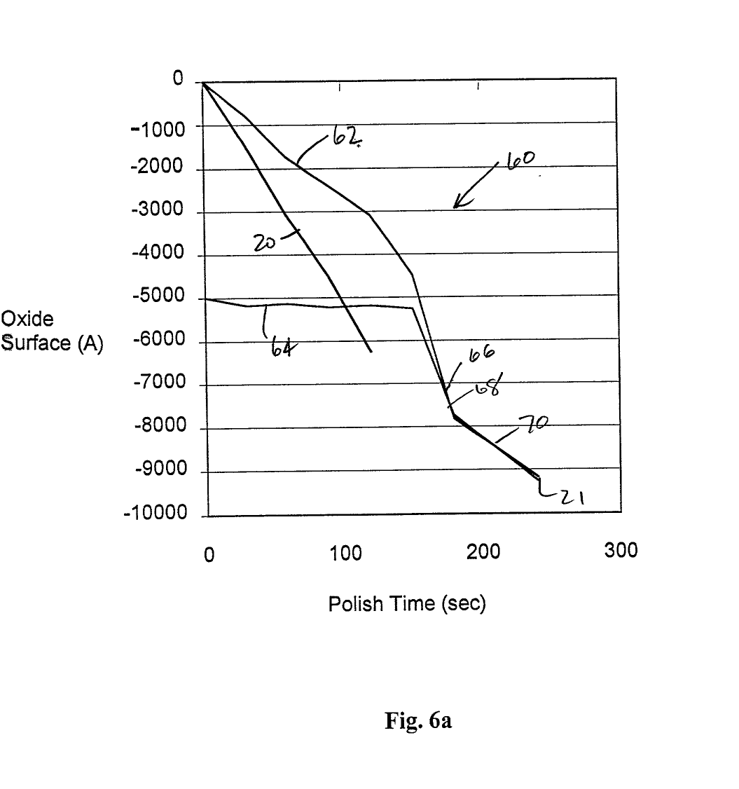

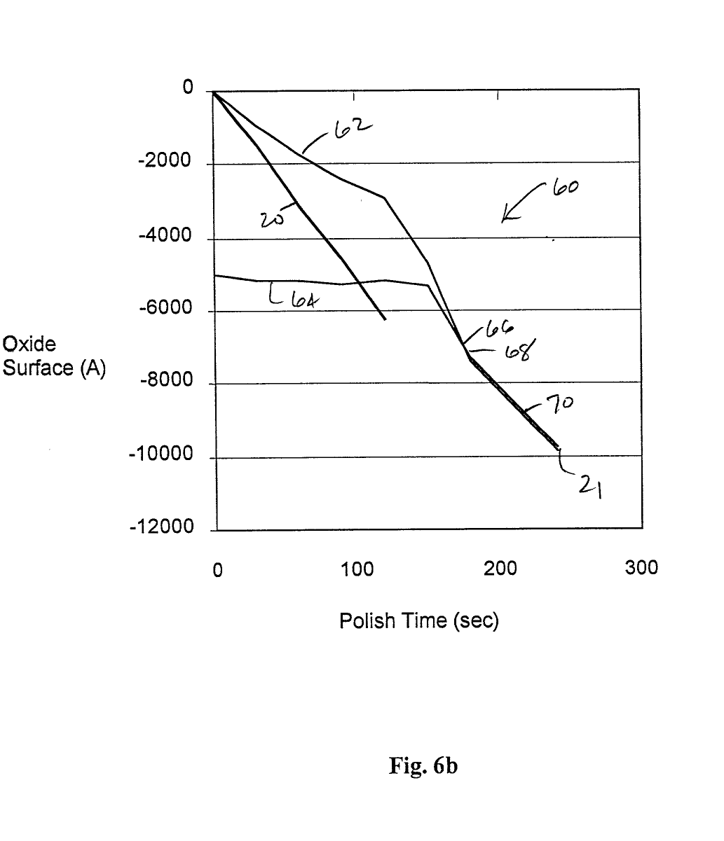

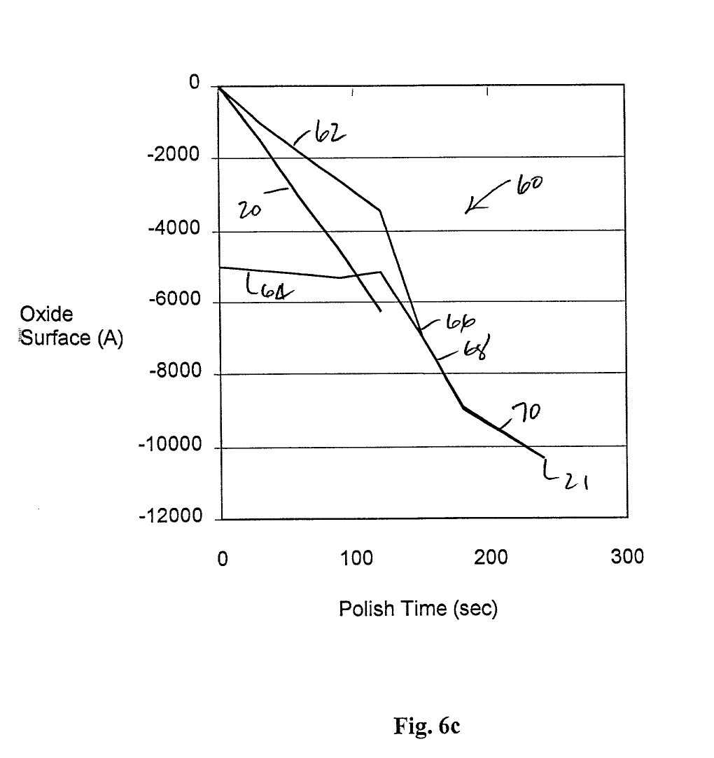

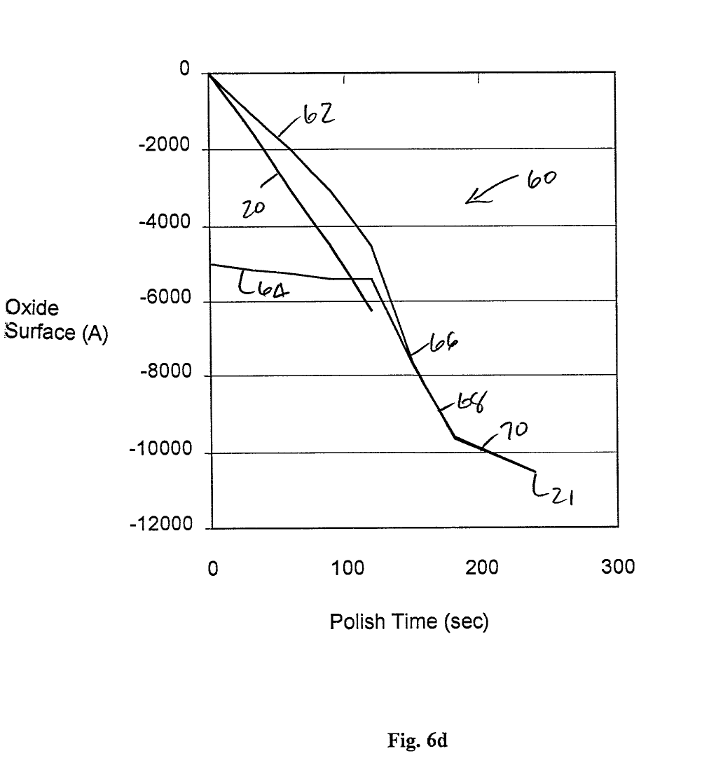

If polishing using ceria slurry is carried out for a sufficiently long time, two important results occur: First, when the substrate surface becomes substantially planarized, polishing characteristics revert back to more conventional behavior. Second, if silicon, polysilicon, or silicon nitride underlie the polished layer of silicon dioxide, they tend to act as a polish stop. These results are illustrated in FIGS. 6a-6d, which depict polishing characteristics for feature size scales corresponding to FIGS. 3 and 5. Long term ceria polishing characteristics are illustrated generally at 60. A high area rate 62 approximates blanket rate 20 over time, while a low area rate 64 is close to zero. Convergence points 66 are reached in some instances, with a converged rate 68 being shown for those instances. Where an appropriate underlying material is present, a polish stop rate 70 is shown.

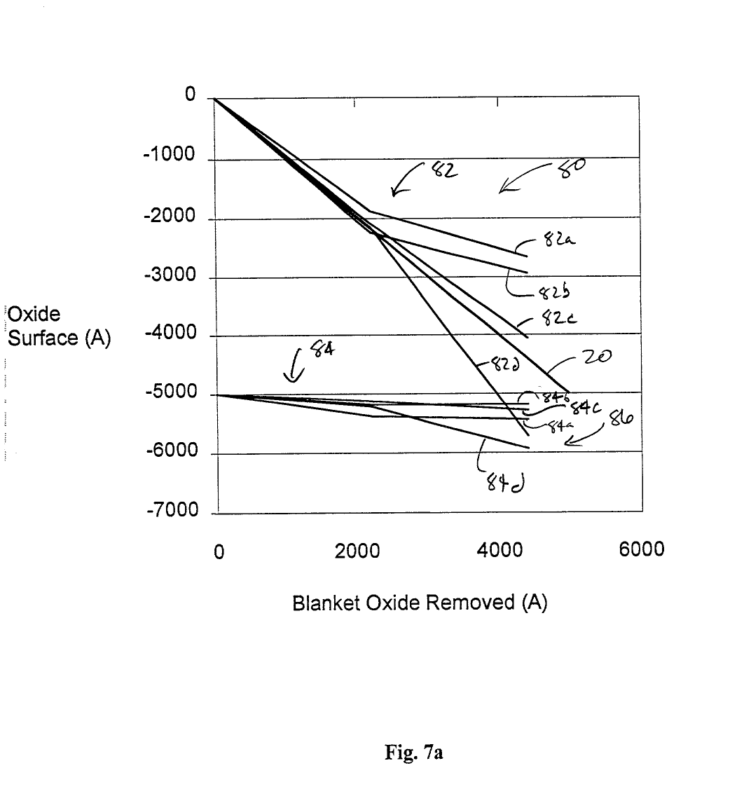

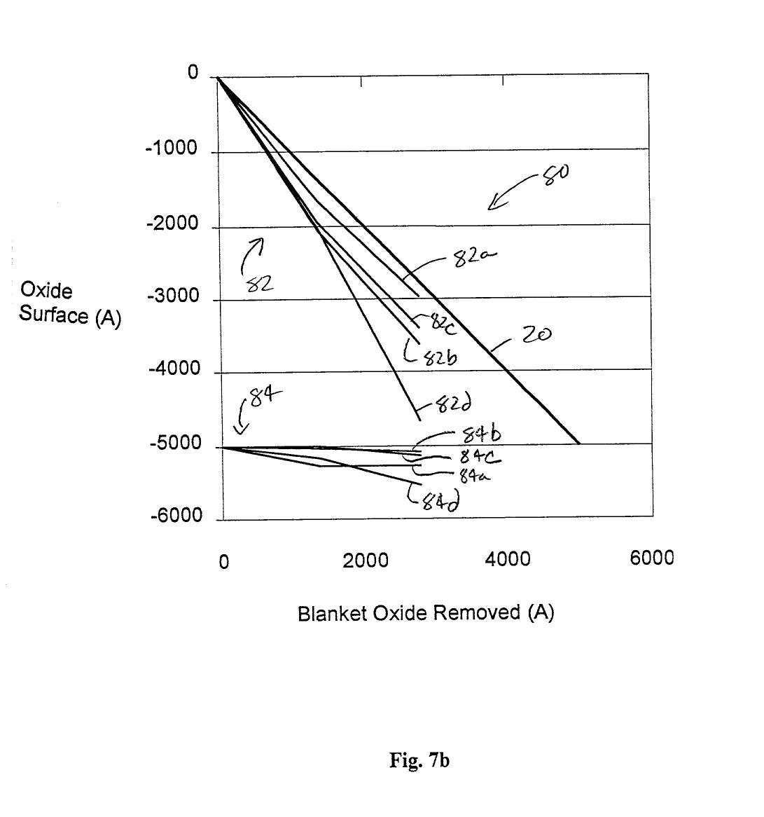

Further testing has demonstrated that addition of a modifier to ceria slurry, in particular ethylene glycol, causes the polishing characteristics illustrated in FIGS. 4, 5 and 6 to become more conventional, as illustrated in FIGS. 2 and 3. This characteristic is shown generally at 80 in FIG. 7, which illustrates the effect of addition of 10% (FIG. 7a) and 20% (FIG. 7b) ethylene glycol, and a down pressure of 6 psi.. A high area rate 82 is approximately the same as blanket rate 20, while a low area rate 84 remains close to zero. Characteristics 82a, 84a, represent a feature size scale of 2×2 μm; characteristics 82b, 84b, represent a feature size scale of 4×4 μm; characteristics 82c, 84c, represent a feature size scale of 8×8 μm; and characteristics 82d, 84d, represent a feature size scale of 16×16 μm. A convergence point 86 is depicted, but not really achieved in the depicted results. Longer polishing times result in the desired convergence and planarization.

A 10%, by volume, addition of ethylene glycol results in the polishing rate of high areas and the blanket polishing rate to be nearly equal. In comparison, for addition of 20% ethylene glycol by volume, the removal rate has fallen below the blanket polish rate. This is similar to conventional behavior. As expected, control wafers polished in slurry with no ethylene glycol modifier show the usual behavior. Ethylene glycol concentrations up to

50% may be used.

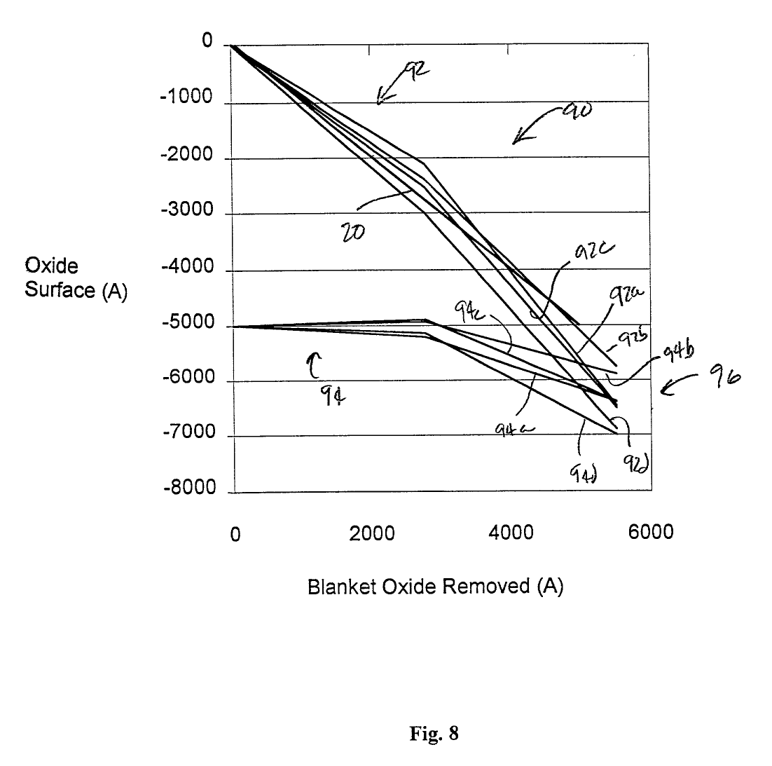

The effect of the modifier can be offset by increasing down force. The effect of a 50% increase in down force, to 9 psi, for a 20% by volume addition of ethylene glycol to ceria slurry is shown in FIG. 8, at 90. A high area rate 92, low area rate 94 and convergence point 96 are depicted, with the characteristics being as described in connection with FIG. 7. The preferred modifier is ethylene glycol, however, other modifiers may work as well provided that they alter physical properties of the slurry in the desired way. The modifier may either be pre-mixed in the slurry feedstock or introduced directly to the polishing table to be mixed with slurry during processing. Ideally, the modifier does not participate in the slurry chemistry, but, only affects slurry physical characteristics, i.e., viscosity, surface tension, etc. or concomitantly, effective slurry layer thickness during the polishing process.

The ideal polishing characteristic of FIG. 1 implies that all pattern dependence may be eliminated because, regardless of size or density, high structure areas polish at the same rate as a flat blanket wafer. Therefore, as the invention is implemented in conjunction with a judicious choice of polishing parameters such as down force, etc., the polishing characteristics of FIG. 1 may be closely approximated. When practicing the preferred embodiment of the invention, a down force of five to ten psi is applied. A table rotation rate of about 20 to 100 rpm is established, as is a spindle rotation rate of about 20 to 100 rpm. A slurry flow rate of 0.50 to 500 ml/min. is maintained.

In a more universal sense, the method of the invention may be used for general global planarization. Use of this method will increase process margin and reduce or eliminate the need to include dummy structures in circuit layouts.

Although a preferred embodiment of the method of the invention has been disclosed herein, it will be appreciated that further variations and modification may be made thereto without departing from the scope of the invention as defined in the appended claims.

I claim:

1. A method of CMP comprising:
forming a CMP slurry containing cerium oxide;
adding a slurry modifier to the slurry, wherein the slurry modifier polishes low structure areas at a substantially zero rate and polishes high structure areas at a rate approximating a blanket polishing rate; and
polishing a structure using the modifier-contained slurry.

2. The method of claim 1 wherein said forming includes setting a cerium oxide concentration of between about 1% and 50% by weight.

3. The method of claim 1 wherein said polishing includes CMP at a pressure of between about five psi and ten psi.

4. The method of claim 1 wherein said adding includes adding ethylene glycol at a concentration of up to 50%.

5. A method of CMP comprising:
forming a CMP slurry containing cerium oxide at a concentration of between about 1% and 50% by weight;
adding a slurry modifier to the slurry, wherein the slurry modifier polishes low structure areas at a substantially zero rate and polishes high structure areas at a rate approximating a blanket polishing rate; and
polishing a structure using the modifier-contained slurry.

6. The method of claim 5 wherein said polishing includes CMP at a pressure of between about five psi and ten psi.

7. The method of claim 5 wherein said adding includes adding ethylene glycol at a concentration of up to 50%.

8. A method of CMP comprising:
forming a CMP slurry containing cerium oxide at a concentration of between about 1% and 50% by weight;
adding ethylene glycol at a concentration of up to 50% for polishing low structure areas at a substantially zero rate and polishing high structure areas at a rate approximating a blanket polishing rate; and
polishing a structure using the slurry.

9. The method of claim 8 wherein said polishing includes CMP at a pressure of between about five psi and ten psi.
